(19) United States
(12) Patent Application Publication
(10) Pub. No.: US 2026/0030409 A1
(43) Pub. Date: Jan. 29, 2026

(54) METHOD FOR REPRESENTING A RESERVOIR INCLUDING THREE TYPES OF MEDIA

(71) Applicant: TotalEnergies OneTech, Courbevoie (FR)

(72) Inventors: Charles Danquigny, Pau (FR); Gérard Massonnat, Pau (FR); Jérémy Ruiu, Pau (FR); Lucie Dal Soglio, Pau (FR)

(21) Appl. No.: 18/572,619

(22) PCT Filed: Apr. 18, 2023
(86) PCT No.: PCT/IB2023/000217

§ 371 Date: Dec. 20, 2023

(51) Int. Cl. G06F 30/23; G06F 30/28

(52) U.S. Cl. CPC G06F 30/23; G06F 30/28

(57) ABSTRACT

A computer-implemented method of building a model of a reservoir that comprises three media including a porous matrix, surface discontinuities within the porous matrix, and conduits within the porous matrix. The method comprises obtaining a three-dimensional meshed model representing the reservoir, the meshed model comprising a plurality of three-dimensional polyhedrons conforming to surface discontinuities and conduits within the reservoir, a surface discontinuity being represented by a 2D meshed surface where each cell of the surface is a face of a 3D polyhedron, and each conduit being represented by a 1D meshed line where each cell of the line is an edge of a polyhedron. A graph model is generated, including a plurality of nodes and connections between adjacent nodes, wherein each node corresponds to a selected one among the three media and is associated with a set of parameters including geometrical parameters and permeability.

### BACKGROUND

### Technical Field

The present disclosure relates to a computer-implemented method for building a model of a reservoir comprising three media including a porous matrix, surface discontinuities within the porous matrix, and conduits within the porous matrix, where the reservoir is suitable for computing a flow field using a finite volume resolution method.

### Description of the Related Art

In order to simulate complex processes within a reservoir related to fluid mechanics, such as fluid flow or diagenetic phenomena induced by fluid flow, it is necessary to build a model of the reservoir that satisfies the twofold condition of faithfully representing reality and respecting technical constraints, in particular computational time, suitability for computer resources, or suitability for the simulation algorithm.

Reservoirs, for instance of carbonate rock, but also of salt, ice or gypsum, can exhibit complex structure including fractures or conduits within a main matrix.

Several attempts have been made to represent reservoirs including a plurality of distinct but interlocking media, having respective geological and physical properties and impacting differently a fluid flow.

For instance, from WO2012/045936, a method for simulating karstification phenomena, corresponding to dissolution of carbonate rock in water, comprises steps of:
defining a gridded geological model of a karstic reservoir, the model describing two media where a first medium is described by values of a geological grid parameter, and a second medium is described by parameters of edges between two nodes of a cell;
simulating stochastic displacements of particles in the grid of the geological model, the probability of each displacement of a particle being calculating by taking into account the medium in which the displacement is carried out; and
modifying the values describing the first and second medium according to the courses taken by the particles.

This document enables modelling the path of the particles in a geological model describing two media. It thus cannot describe accurately a model comprising three media such as a porous matrix, conduits, and surface discontinuities.

A computer program developed by the company DHI group under the name FEFLOW (standing for Finite Element subsurface FLOW system), for simulating groundwater flow, enables representing a reservoir using a meshed model conforming to surface discontinuities, such as fractures or faults, and conduits. However, this program applies the Finite Element method. Calculation is performed on the nodes of the meshed model, making it impossible to take into account complex interactions between matrix volumes, discontinuities, and conduits.

### BRIEF SUMMARY

The present disclosure aims at improving the prior art.

In particular, an aim of the present disclosure is to provide a method for representing a reservoir comprising three different but interlocking media and enabling computation of a flow field using a finite volume resolution method.

To this end, disclosed herein is a computer-implemented method of building a model of a reservoir, in view of computing a flow field within the reservoir model using a finite volume resolution method,
wherein the reservoir comprises three interlocking media including a porous matrix, surface discontinuities within the porous matrix, and conduits within the porous matrix,
the method comprising:
   obtaining a three-dimensional meshed model representing the reservoir, the meshed model comprising a plurality of three-dimensional polyhedrons conforming to surface discontinuities and conduits within the reservoir, a surface discontinuity being represented by a 2D meshed surface where each cell of the surface is a face of a 3D polyhedron, and each conduit being represented by a 1D meshed line where each cell of the line is an edge of a polyhedron, and
   generating a graph model from the three-dimensional meshed model, the graph model comprising a plurality of nodes and connections between adjacent nodes, wherein:
      each node corresponds to a selected one among the three media and is associated with a set of parameters including geometrical parameters and permeability,
      the connections between the nodes include connections between two nodes corresponding to the same medium and connections between nodes corresponding to any two different media, and
      each connection between two nodes is associated with a transmissibility value determined from the medium to which belong the two nodes linked by the connection and their respective associated set of parameters.

In embodiments, the graph model is a complete graph wherein each node is connected to all the adjacent nodes.

In embodiments, generating the graph model from the three-dimensional meshed model comprises:
generating nodes corresponding to the porous matrix at the center of each polyhedron;
generating nodes corresponding to the surface discontinuities at the center of each face of polyhedron forming a 2D meshed surface representing a surface discontinuity;
generating nodes corresponding to the conduits at the center of each edge of polyhedron forming a 1D meshed line representing a conduit; and
generating connections between each pair of adjacent nodes.

In this case, each polyhedron may be defined by geometrical parameters, and generating the graph model from the 3D meshed model may further comprise determining geometrical parameters associated with each node, the parameter of volume being derived from the geometrical parameters of the polyhedrons.

In embodiments, the geometrical parameters associated with a node corresponding to a conduit comprise at least a length and one among the following: a volume, a diameter or a radius.

In embodiments, the geometrical parameters associated with a node corresponding to a surface discontinuity comprise at least a surface and one among the following: a volume, an aperture.

In embodiments, the method may further comprise determining a permeability value of a node corresponding to a conduit or a surface discontinuity from the geometrical parameters of the node.

In embodiments, the method further comprises determining the transmissibility value of a connection between two nodes based on the permeability values of the two nodes and the geometrical parameters associated with the nodes.

In embodiments, each node of the graph model is associated with a volume of void parameter, and:
the volume of void parameter assigned to a node corresponding to the porous matrix comprises one of a volume of void value of the porous matrix or a porosity value;
the volume of void parameter assigned to a node corresponding to a surface discontinuity comprises one of a volume value or an aperture; and
the volume of void parameter assigned to a node corresponding to a conduit comprises one of a volume value, a radius or a diameter.

According to another object, it is disclosed a method of computing a flow field within a model of a reservoir, wherein the reservoir comprises three media including a porous matrix, surface discontinuities within the porous matrix and conduits within the porous matrix, the method comprising:
building a graph model of the reservoir by application of the method disclosed above; and
computing a flow field within the reservoir, using a finite volume resolution method applied to the graph model.

In embodiments, this method further comprises simulating reactive transport within the reservoir based on the computed flow field. Simulating reactive transport within the reservoir may comprise simulating the displacement of particles representing a fluid along a path within the graph model of the reservoir, and updating at least some of the parameters associated with the nodes of the path of the particles. The method may further comprise updating the meshed model of the reservoir according to the updated parameters associated with the nodes of the graph model, and displaying the updated meshed model.

According to another aspect, a computer-program product is disclosed, comprising code instructions for implementing the methods disclosed above, when it is executed by a computer.

According to another aspect, a computing device is disclosed, comprising at least a processor and a memory, the computing device being configured for implementing the methods disclosed above.

According to another aspect, disclosed herein is a non-transitory computer-readable storage medium having stored thereon instructions which, when executed by at least one processor, cause the processor to carry out the method according to the description above.

The proposed method enables building a graph representing a reservoir comprising three media from a meshed model, wherein all the nodes of the graph belong to a respective one among the three media, and all the connections between the nodes, whatever the medium to which belong the connected nodes, are associated with a transmissibility value. The structure of the graph and its parametrization enable computing a flow field relying on a finite volume resolution method, which is thus simpler than the prior art and enables performing simulation of fluid flow phenomena reliably (e.g., respect of the local mass balance) and using fewer computational resources. Moreover, a resolution performed based on a finite volume resolution method enables representing the interactions between diverse media, such barrier surfaces within a porous matrix.

### BRIEF DESCRIPTION OF THE SEVERAL VIEWS OF THE DRAWINGS

Other features and advantages of the present disclosure will be apparent from the following detailed description given by way of non-limiting example, with reference to the accompanying drawings, in which:

FIG. 1 schematically represents the main steps of a method according to an embodiment.

FIG. 2a represents an exemplary graph model that may be used in the method according to an embodiment, and FIG. 2b represents a three-dimensional mesh from which the graph model is obtained.

FIGS. 3a to 3f represent conventions of notations for computing transmissibility between nodes of the graph model.

FIG. 4 schematically represents a device for implementing the method.

FIG. 5 represents an example of polyhedron of a 3D mesh from which nodes are generated.

### DETAILED DESCRIPTION

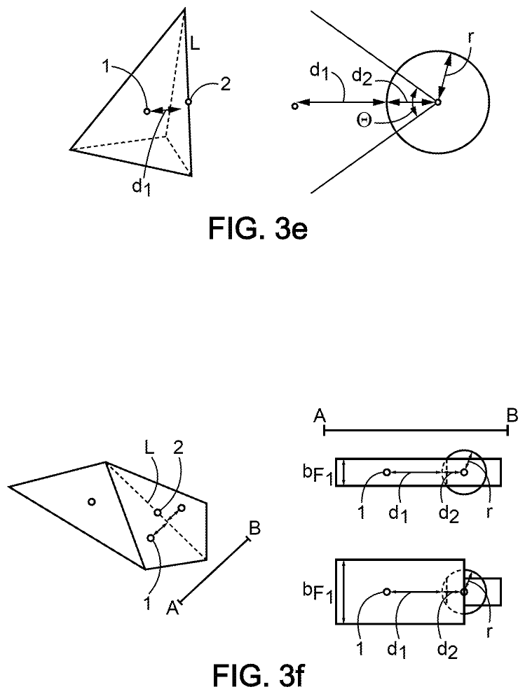

Embodiments of a computer-implemented method for building a model of a reservoir will now be disclosed. With reference to FIG. 4, the method may be implemented by a device 10 comprising a computer, this computer comprising a memory 15 to store program instructions loadable into a circuit and adapted to cause circuit 14 to carry out the steps of the method when the program instructions are run by the circuit 14.

The memory 15 may also store data and useful information for carrying the steps of the method.

The circuit 14 may be for instance:
a processor or a processing unit adapted to interpret instructions in a computer language, the processor or the processing unit may comprise, may be associated with or be attached to a memory comprising the instructions; or
the association of a processor/processing unit and a memory, the processor or the processing unit adapted to interpret instructions in a computer language, the memory comprising said instructions; or
an electronic card wherein the steps of the disclosure are described within silicon; or
a programmable electronic chip such as a FPGA chip (for «Field-Programmable Gate Array»).

This computer comprises an input interface 13 for the reception of several data used for the method for building a reservoir, for instance the graph model or a three-dimensional meshed model from which the graph model may be obtained, some parameters of the topography of the modelled reservoir, parameters regarding the boundary conditions of a fluid flow to be simulated through the reservoir, etc. This computer also comprises an output interface 16 for outputting updated data regarding the reservoir. The output interface may comprise a display for displaying the obtained model.

To ease the interaction with the computer, a screen 11, and a keyboard 12 or a tactile screen may be provided and connected to the computer circuit 14. The various components described above may be remotely connected to one another, i.e., the memory storing the data and/or the circuit implementing the method may be remotely located with reference to the user and accessible through any suitable network.

The modelled reservoir may be a carbonate reservoir, possibly including karst features, but may also be a reservoir of salt, of gypse, of ice, or any other material in which there is interest to consider discontinuities and/or conduits.

The modelled reservoir may correspond to a real reservoir, from which parameters describing the geometry, topography, the nature of rock, facies types, etc., may be acquired.

The method enables computing a flow field within the reservoir model. The computed flow field may then be used for simulating fluid flow within the reservoir from an input location towards an output location, and for simulating phenomena caused by the rock-fluid interactions along the flow path, such as diagenetic phenomena.

The method may for instance be implemented with a view to simulating the evolution of a reservoir from a previous state until a later state, for instance from a past state until a current state observable in reality, or from a current state observable in reality until a future state. Thus, the method may allow better understanding the geometry of the current state of a reservoir, and predicting circulation of fluid flows or locate underground cavities. According to an example, the method may for instance be implemented for predicting circulation of pollutants in a karstic reservoir, in order to prevent or anticipate groundwater contamination. According to another example, the method may be implemented in order to ensure that a construction may be built at a defined location, while avoiding any risk of collapse due to underground cavities. According to still another example, the method may be implemented in order to better understand the configuration of a karstic reservoir and allow enhanced oil or gas recovery, or monitor carbon dioxide injection for underground storage. Thus, the method may be implemented with a view to at least one of the following applications: groundwater resources management, hydrocarbon recovery, carbon dioxide storage, civil engineering, urbanism, agriculture.

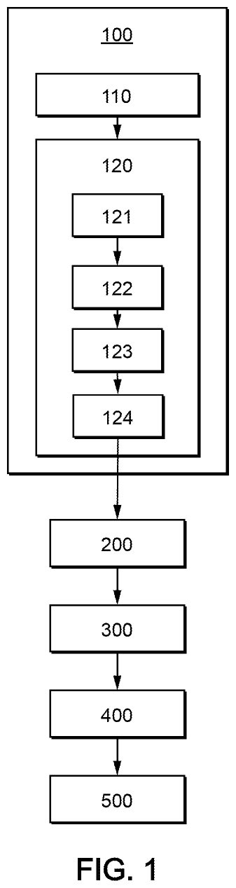

With reference to FIG. 1, the main steps of a method 100 for building a graph model of a reservoir will now be disclosed.

The reservoir comprises three distinct media within which the fluid may flow, and which are represented by the graph model, wherein the three media comprise:
the porous matrix of rock, or any other material (salt, ice . . . ), constituting the reservoir, the term “porous matrix” not being limited, in what is described below, to a reservoir of rock, but can also designate a matrix of salt, ice, or any other relevant porous material;
surface discontinuities, such as faults, fractures, or horizons extending within the porous matrix, within which fluid may flow; and
conduits extending within the porous matrix, the conduits being generally linear discontinuities within which the fluid may flow.

The method comprises generating a graph model of the reservoir from a three-dimensional meshed model representing the reservoir. It thus comprises a step 110 of receiving a three-dimensional meshed model representing the reservoir, and a step 120 of generating, from said three-dimensional meshed model, a graph model.

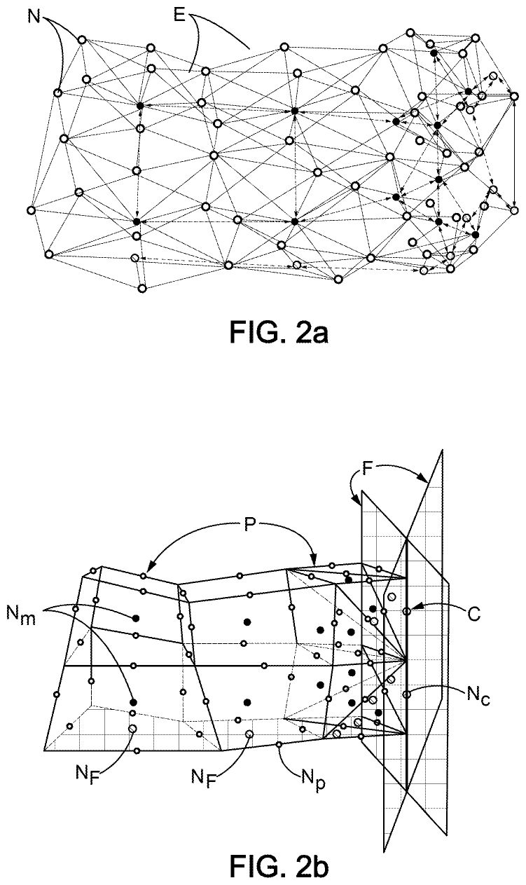

With reference to FIG. 2b, the three-dimensional meshed model comprises a plurality of three-dimensional polyhedrons P, each polyhedron being defined by a plurality of vertices, i.e., of three-dimensional points associated with three-dimensional coordinates. Each polyhedron is also defined by a plurality of two-dimensional planar faces, where each face is defined by at least three vertices, and a plurality of one-dimensional edges forming the sides of a face, each edge being a connection between two vertices. According to a non-limiting example, the polyhedrons may be tetrahedrons or hexahedrons. The three-dimensional polyhedrons may further be associated with petrophysical parameters, including for instance values of porosity, permeability, a type of material or facies, a type of facies environment, etc., that describe the petrophysical properties of the reservoir.

Furthermore, the three-dimensional meshed model conforms to surface discontinuities of the reservoir, which means that the shapes of the polyhedrons neighboring a surface discontinuity which is represented in the meshed model conform to that surface discontinuity. Hence, the surface discontinuities are represented in the three-dimensional meshed model by meshes surface where each cell of the surface is a two-dimensional face of a 3D polyhedron.

The three-dimensional meshed model also conforms to conduits, which means that the shapes of the polyhedrons neighboring a conduit represented in the meshed model conforms to that conduit. Hence, the conduits are represented in the three-dimensional meshed model by one-dimensional meshed lines, which cells are formed by one or more consecutive edges of polyhedra.

The generation 120 of this three-dimensional meshed model into the graph model comprises generating nodes 121 and generating connections 122 between the nodes, where each node corresponds to a selected one among the three media, i.e., the porous matrix, a surface discontinuity or a conduit. As described in more details below, connections between the nodes are generated for any two adjacent nodes, whatever the medium to which belong the adjacent nodes, and even if the adjacent nodes correspond to two different media. Hence, the graph is a complete graph.

Further, nodes are associated with parameters 123 which may be derived from the meshed model, and transmissibility values are associated 124 to the connections between the nodes.

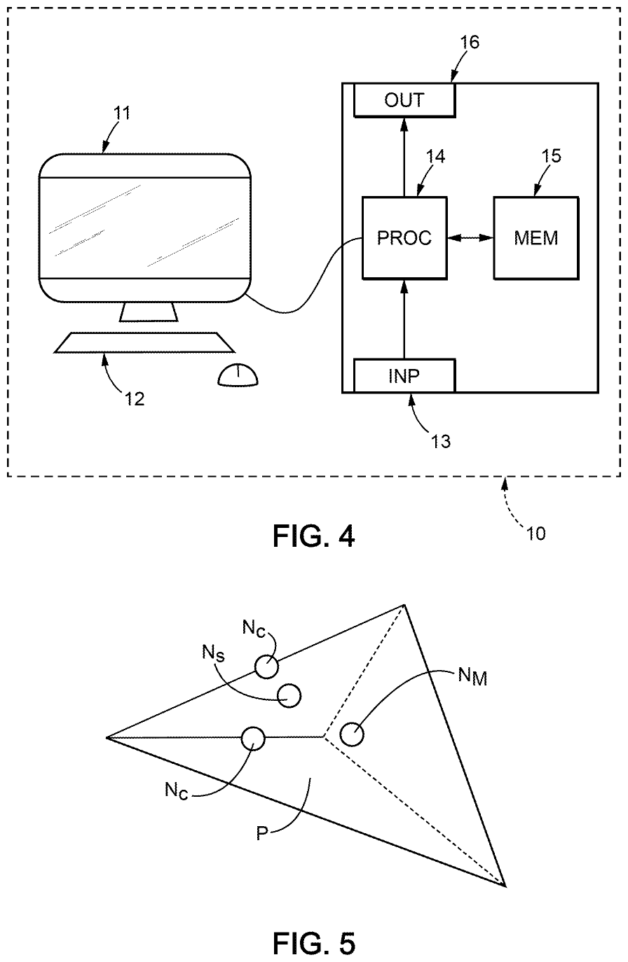

More specifically, and with reference to FIG. 5 showing exemplary nodes generated from a polyhedron, wherein one face of the polyhedron belongs to a surface discontinuity and two edges of the polyhedron belong to conduits, the generation of the graph from the meshed model comprises generating 121:
nodes Nₘ corresponding to the porous matrix at the center of each polyhedron;
nodes Nₛ corresponding to the surface discontinuities, said nodes being located at the center of each cell of a surface discontinuity, i.e., at the center of each face of a polyhedron conforming to the surface discontinuity; and
nodes N_{c} corresponding to the conduits C at the center of each edge of a conduit, i.e., at the center of each edge of a polyhedron conforming to the conduit.

Connections are then generated at step 122 between all adjacent nodes, whatever the media to which belong the nodes.

The generation of the graph model then comprises associating 123 information to each node. This comprises computing and associating three-dimensional coordinates to each node, the coordinates being computed from the coordinates of the vertices of the meshed model.

It also comprises associating at least one parameter to each node. The at least one parameter may include:
geometrical parameters, which are inferred from the geometry of the initial meshed model;
at least a value of volume of the geological element represented by the node, or a volume of void parameter; and
a permeability value.

Regarding the nodes Nₛ corresponding to surface discontinuities, the geometrical parameters assigned to the nodes may comprise at least one among: a volume, an aperture, or a surface. In embodiments, the geometrical parameters comprise at least an aperture b_{F}_{ⱼ} of the surface discontinuity, and an area A_{F}_{ⱼ} associated with the node, where j is the index of the node. The area associated with the node corresponds to the area of the face of the polyhedron from which the node has been generated, or, when a conduit is located on an edge of said face, as for instance in FIG. 5, it corresponds to the area A_{P}_{ⱼ} of the face of the polyhedron minus the area represented by the conduit k of diameter D_{C}_{ₖ} and length L_{C}_{ₖ}:

$${A}_{{F}_{j}} = {A}_{{P}_{j}} - ( \frac{{D}_{{C}_{k}}}{2} {L}_{{C}_{k}} )$$

The volume of the surface discontinuity may then be computed as the product of the area and aperture: V_{F}_{ⱼ}=b_{F}_{ⱼ}·A_{F}_{ⱼ}. This volume corresponds to a volume of void.

The permeability of a node corresponding to a surface discontinuity may be computed from aperture as follows:

$${K}_{{F}_{j}} = \frac{{{b}_{{F}_{j}}}^{2} ρ g}{12 μ} = \frac{{{b}_{{F}_{j}}}^{2} g}{12 v}$$

where μ is the dynamic viscosity and v is the kinematic viscosity of the considered fluid.

Regarding the nodes N_{C} corresponding to conduits, the geometrical parameters assigned to the nodes may comprise at least one among a volume, a diameter or radius, and a length. In embodiments, the geometrical parameters comprise at least a length L_{C}_{ₖ} of the conduit, which is the length of the edge of the polyhedron from which the node has been generated, and a diameter D_{C}_{ₖ} or radius. The diameter or radius of the conduit may be derived from the diameter of the radius of the conduit represented in the meshed model.

The volume of the conduit may then be computed as:

$${V}_{{C}_{k}} = {π ( \frac{{D}_{{C}_{k}}}{2} )}^{2} {L}_{{C}_{k}}$$

The permeability of a node corresponding to a conduit may be computed as follows:

$$log ( {K}_{{C}_{k}} ) = \frac{1}{3} log ( {Kl}_{{C}_{k}} ) + \frac{2}{3} log ( {Kt}_{{C}_{k}} )$$

$${Kl}_{{C}_{k}} = \frac{g \cdot {{D}_{{C}_{k}}}^{2}}{32 v ( 1 + 8.8 {kr}^{3 / 2} )}$$

$${Kt}_{{C}_{k}} = 2 log ( \frac{1.9}{kr} ) \sqrt{2 g \cdot {D}_{{C}_{k}}}$$

where kᵣ is the relative rugosity of the material forming the porous matrix.

Regarding the nodes N_{M} belonging to the porous matrix, the associated parameters may include parameters representative of a volume of rock represented by the node, and volume of void parameters. Indeed, the volume V_{P}_{ᵢ} of the polyhedron from which the node has been generated, and which is defined by the 3D coordinates of the vertices defining the polyhedron, comprises a volume of rock and a volume of void: V_{P}_{ᵢ}=V_{V}_{ᵢ}+V_{R}_{ᵢ}.

The volume of void V_{V}_{ᵢ} includes:
the volume of void resulting from porosity within the porous matrix; optionally, the volume of a part of the one or more surface discontinuities at corresponding faces of the polyhedron, i.e., half the volume of each surface discontinuity located at a corresponding face of the polyhedron, since one surface extends between two polyhedra;
optionally, the volume of part of the one or more conduits at corresponding edges of the polyhedrons, i.e., the volume of the part of the conduit contained by the polyhedron:

$${V}_{{V}_{i}} = {V}_{{M}_{i}} \cdot {∅}_{i} + {\sum }_{j = 1}^{jFi} {V}_{{F}_{j , i}} + {\sum }_{k = 1}^{kCi} {V}_{{C}_{k , i}}$$

where V_{M}_{ᵢ} is the volume of the porous matrix of the polyhedron i, V_{F}_{_{j,i}} is the part of the volume of a surface discontinuity j on a surface of the polyhedron i belonging to this polyhedron, and V_{C}_{_{k,i}} is the part of the volume of a conduit k on an edge of the polyhedron i belonging to this polyhedron.

The volume of rock V_{R}_{ᵢ} is the volume of the solid matrix from which is deduced the volume of void resulting from porosity ∅ᵢ: V_{R}_{ᵢ}=V_{M}_{ᵢ}·(1−∅ᵢ). The volume of void parameters associated with a node thus comprise porosity and the volume of void Vᵥᵢ of the node.

The permeability value of the node may also be equal to the permeability associated with the polyhedron from which the node has been generated, if this parameter is defined. Alternatively, an initial porosity may be associated with a polyhedron or to the node generated from the polyhedron, and an initial permeability of the node may be derived from the porosity, for instance by application of a formula of the type:

$$log ( {K}_{i} ) = A {∅}_{i} + B$$

where Kᵢ is the permeability of the node and A and B are constants that depend upon the material forming the porous matrix.

Once permeability values are associated with the nodes of the graphs, the method further comprise a step 124 of computing transmissibility values associated with the connections between the nodes. The transmissibility values may be computed from the permeability values associated with the two nodes that are linked by a connection, and from the geometry of the elements of the 3D meshed model from which the nodes have been derived.

According to a general description, the transmissibility may be computed according to a Two Points Flux Approximation, wherein if two nodes connected by a connection are denoted 1 and 2, then the transmissibility of the connection may be computed as follows:

$${T}_{1 , 2} = \frac{{T}_{1} \cdot {T}_{2}}{{T}_{1} + {T}_{2}}$$

where T1, resp. T2, denotes the transmissibility between the node 1, resp. 2 and a surface at the interface between the two objects to which correspond the nodes, also denoted as contact surface. Tᵢ, where i equals 1 or 2, can be defined as follows:

$${T}_{i} = \frac{{K}_{i} \cdot \vec{{d}_{ι}} \cdot \vec{{n}_{ι}} \cdot {A}_{i , j}}{{‖ \vec{{d}_{ι}} ‖}^{2}}$$

where \vec{d_{ι}} is the vector between node i and the center of the contact surface between the nodes 1 and 2, \vec{n_{ι}} is the normal to the contact surface; A_{i,S} the area of the contact surface of the element represented by node i with the element represented by node j, as seen from the node i and Kᵢ is the permeability of the node i.

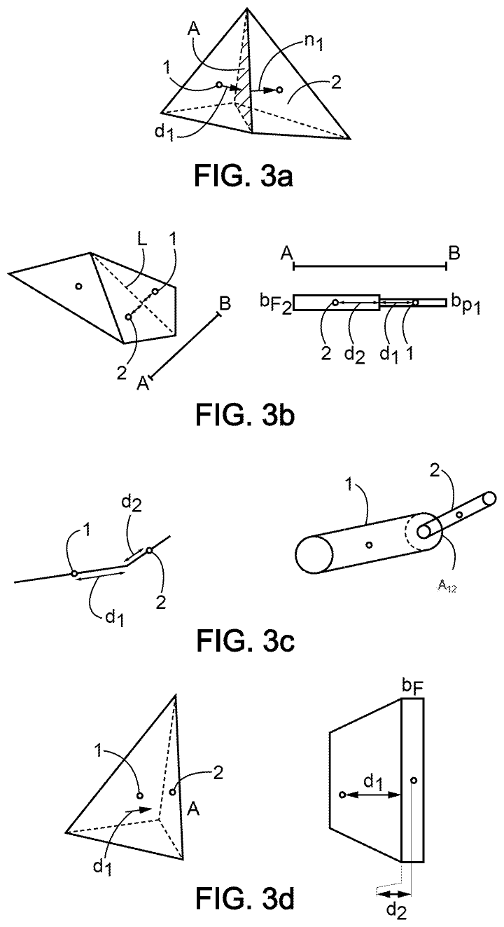

With reference to FIG. 3a, for the calculation of transmissibility between two nodes corresponding to a porous matrix, the contact surface is defined as the face in common between the two polyhedrons from which the nodes have been generated. The transmissibility Ti for each zone may thus be readily computed from the equation above.

With reference to FIG. 3b, for the calculation of transmissibility between two nodes corresponding to a surface discontinuity, these nodes have been generated at the center of faces of polyhedrons. The faces from which the nodes have been generated share a common edge since the nodes are adjacent. Let L_{i,j} be the length of the common edge at the intersection of the considered faces, the area A_{i,j} of the contact surface between the nodes. considered from node i, is equal to

$${A}_{i , j} = {b}_{{F}_{i}} {L}_{i , j}$$

where b_{F}_{ᵢ}i is the aperture of node i. The vector \vec{d_{ι}} in that case is the vector between the node and the center of the segment, and the vector \vec{n_{ι}} is the normal to the segment that is included within the plane of the face from which the node has been generated. The same applies mutatis mutandis for the computation of the area A_{j,i} of the contact surface between the nodes, considered from node j.

With reference to FIG. 3c, for the calculation of transmissibility between two nodes corresponding to a conduit, these nodes have been generated at the center of an edge of a polyhedron.

\vec{d_{ι}}·\vec{n_{ι}} is half of the length of the edge from which the node has been generated. Considered from node I, A_{i,j}=πrᵢ² where rᵢ is the radius of the conduit corresponding to node i. The same applies mutatis mutandis for the computation of the area A_{j,i} of the contact surface between the nodes, considered from node j.

With reference to FIG. 3d, for the calculation of transmissibility between a node corresponding to a surface discontinuity and a node corresponding to the porous matrix, the contact surface corresponds to the face of the polyhedron that conforms to the surface discontinuities and at the center of which the node corresponding to the porous matrix has been generated. Its area is derived from the meshed model. The distance between the node corresponding to the surface discontinuity and the surface is equal to b_{F}/2 where b_{F} is the aperture of the surface discontinuity.

With reference to FIG. 3e, for the calculation of transmissibility between a node corresponding to a conduit and a node corresponding to the porous matrix, the conduit corresponds to an edge of the polyhedron from which the node corresponding to the porous matrix has been generated and hence the contact surface is defined by the curvilinear section of the conduit that is inside the polyhedron. This surface A_{c} may be computed from the radius of the conduit and the angle θ (rad) formed by the faces of the polyhedron intersecting at the edge corresponding to the conduit, according to the following equation:

$${A}_{c} = r θ L$$

where L is the length of the edge.

dᵢ, on the side of the node corresponding to the conduit, is equal to the radius of the conduit, and dⱼ on the side of the node corresponding to the porous matrix, is equal to the distance between the node and the edge, minus the radius of the conduit.

With reference to FIG. 3f, for the calculation of transmissibility between a node corresponding to a conduit and a node corresponding to a surface discontinuity, the node corresponding to the conduit is located at an edge of the surface corresponding to the surface discontinuity.

Thus, if i denotes the node corresponding to the conduit and j denotes the node corresponding to the surface discontinuity:

$${A}_{i , j} = {A}_{j , i} = π \cdot {r}_{i} \cdot L , if {r}_{i} < {b}_{{F}_{j}} ,$$

which is the example represented in the upper, right-hand side of FIG. 3f; and

$${A}_{i , j} = {A}_{j , i} = {b}_{{F}_{j}} \cdot L , if {r}_{i} \geq {b}_{{F}_{j}} ,$$

where L is the length of the edge at the center of which is the node corresponding to the conduit, b_{F}_{ⱼ} is the aperture of the surface discontinuity and rᵢ is the radius of the conduit.

dᵢ on the side of the conduit is equal to the radius of the conduit and, dⱼ on the side of the surface discontinuity, is equal to the distance between the node and the edge corresponding to the conduit, minus the radius of the conduit.

Accordingly, a complete graph model representing three different interlocking media is obtained, wherein the nodes corresponding to the three media are connected by connections which are all associated with a same type of parameter, i.e., transmissibility, even when the connected nodes belong to different media.

It is therefore possible to use the obtained graph in order to compute a flow field within the reservoir, and simulate, from said flow field, reactive transport within the reservoir, i.e., chemical reactions consecutive to the flowing of fluid within the reservoir. Reactive transport can include phenomena of dissolution, cementation, mineralogic change, precipitation, etc.

In embodiments, the three-dimensional meshed model is nevertheless kept in a memory in order to be later updated, as disclosed in more details below.

In embodiments, in order to compute the flow field, the method disclosed above may be followed by a step 200 of defining flow boundary conditions of the graph model.

The flow boundary conditions may comprise input boundary conditions. The input boundary conditions can comprise one or more input locations for the fluid within the reservoir. According to an embodiment, the input location for the fluid may be formed by an entrance surface called a recharge area, formed by a plurality of nodes defined by the user.

For instance, the recharge area may be a top surface, i.e., located at the roof of the reservoir, considering the axis top-bottom as the axis of the gravity.

The input boundary conditions may also comprise an amount of fluid entering the reservoir during the time period, which may be expressed explicitly or controlled by a hydraulic head. In what follows, let Re be the volume of fluid that enters the graph during the time period, in m³.

The flow boundary conditions may also comprise output boundary conditions, which can comprise one or more output locations for the fluid, and an amount of fluid exiting the reservoir, which can be expressed explicitly, or controlled by a hydraulic head at the output location.

A steady state flow field within the graph model may then be computed during a step 300, from the boundary conditions and by application of both mass conservation and Darcy's laws, the latter describing the flow of a fluid through a porous medium. As the reservoir model is a complete graph, i.e., a graph where each node is connected to all adjacent nodes, where the three media are all represented by nodes, and the connections between two nodes, whatever the medium to which they belong, are associated with a parameter of transmissibility, the computation of the flow field can be performed using a finite volume resolution method known to the skilled person.

The steady state flow field may then be used for simulating 400 reactive transport within the reservoir. Simulating reactive transport within the reservoir comprises simulating fluid flowing through the reservoir and updating the parameters of at least some nodes of the reservoir as a consequence of said fluid flow, and depending on the type of reactive transport that is simulated.

Simulating fluid flow may be achieved by simulating the displacement of a plurality of particles representing the fluid through the reservoir. A path of each particle may be determined from the computed flow field, said path being formed by a sequence of adjacent nodes of the reservoir.

The type of parameter that is updated and the way the parameters are updated then depend upon the type of reactive transport that is simulated. According to a non-limiting example, when the simulated reactive transport is dissolution, each particle representing fluid flow may be associated with a volume of rock that the particle is able to dissolve within a given time period.

Further, once the path of a particle has been determined, updating the parameters of the nodes of the path of the particle may comprise computing a volume of rock that is dissolved by the particle in each node of its path. The dissolved volume of rock may then be converted into updated geometrical parameters (diameter and volume of the conduits, aperture and volume of the surface discontinuities), and/or updated volume of void parameters (porosity of the porous matrix) of the nodes of the path. From these updated parameters, updated permeability values may also be computed for the nodes of the path of the particle. Then, updated transmissibility values may be computed for the connections between the nodes.

The above steps of computing a flow field 300 and simulating 400 reactive transport can be iterated a number of times. Optionally, the definition 200 of the flow boundary conditions may also be amended between two iterations of steps 300 and 400.

In embodiments, after at least one iteration or after a series of consecutive iterations, the updated parameters of the graph model may be used to update the three-dimensional meshed model from which the graph has been generated, and to display 500 a graphical representation of the updated meshed model. Indeed, as the meshed model conforms to surface discontinuities and conduits, it is easier for an operator to understand the disposition and size of said surface discontinuities and conduits, and to compare them with a different state, for instance a previous state, than by analyzing or visualizing a graph.

In particular, when nodes corresponding to conduits or surface discontinuities exhibit increased volume, i.e., increase diameter or aperture, then the increased diameter or aperture can be apparent in the displayed 3D meshed model. According to a non-limiting example, the increase in diameter or aperture may be displayed using a specific color denoting respectively an increase; a decrease, or an increase within a determined, or a decrease within a determined range. According to another example, specific colors may be associated with determined ranges of diameter or aperture, enabling to differentiate visually the conduits and surface discontinuities according to their size. The updated diameters of the conduits or updated apertures of the surfaces may also be displayed visually, for instance by the thickness of the line or shape representing the conduit or aperture. Moreover, it is also possible to display only the network of conduits and/or the network of surface discontinuities, i.e., without the parts of the meshed model representing the porous matrix.

The various embodiments described above can be combined to provide further embodiments. All of the patents, applications, and publications referred to in this specification and/or listed in the Application Data Sheet are incorporated herein by reference, in their entirety. Aspects of the embodiments can be modified, if necessary to employ concepts of the various patents, applications, and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled.

1. A computer-implemented method of building a model of a reservoir,
the method comprising:
obtaining a three-dimensional meshed model representing the reservoir, wherein the reservoir comprises three interlocking media including a porous matrix, surface discontinuities within the porous matrix, and conduits within the porous matrix, the three-dimensional meshed model comprising a plurality of three-dimensional polyhedrons conforming to the surface discontinuities and conduits of the reservoir, a surface discontinuity being represented in the three-dimensional meshed model by a two-dimensional (2D) meshed surface where each cell of the surface is a face of a three-dimensional (3D) polyhedron, and each conduit being represented by a one-dimensional (1D) meshed line where each cell of the line is an edge of a polyhedron; and
generating a graph model from the three-dimensional meshed model, the graph model comprising a plurality of nodes and connections between adjacent nodes, wherein:
each node corresponds to a selected one among the three interlocking media and is associated to a set of parameters including geometrical parameters and permeability;
the connections between the adjacent nodes include connections between two nodes corresponding to the same medium and connections between nodes corresponding to any two different media; and
each connection between two nodes is associated with a transmissibility value determined from the medium to which belong the two nodes linked by the connection and their respective associated set of parameters.

2. The method according to claim 1, wherein the graph model is a complete graph wherein each node is connected to all the adjacent nodes.

3. The method according to claim 1, wherein generating the graph model from the three-dimensional meshed model comprises:
generating nodes corresponding to the porous matrix at the center of each polyhedron;
generating nodes corresponding to the surface discontinuities at the center of each face of the polyhedron forming a 2D meshed surface representing a surface discontinuity;
generating nodes corresponding to the conduits at the center of each edge of the polyhedron forming a 1D meshed line representing a conduit; and
generating connections between each pair of adjacent nodes.

4. The method according to claim 3, wherein each polyhedron is defined by geometrical parameters, and generating the graph model from the 3D meshed model further comprises determining geometrical parameters associated with each node, the parameter of volume being derived from the geometrical parameters of the polyhedrons.

5. The method according to claim 1, wherein the geometrical parameters associated with a node corresponding to a conduit comprise a length and at least one among the following: a volume, a diameter, or a radius.

6. The method according to claim 1, wherein the geometrical parameters associated with a node corresponding to a surface discontinuity comprise a surface and at least one among the following: a volume, an aperture, or a surface.

7. The method according to claim 4, further comprising determining a permeability value of a node corresponding to a conduit or a surface discontinuity from the geometrical parameters of the node.

8. The method according to claim 7, further comprising determining the transmissibility value of a connection between two nodes based on the permeability values of the two nodes and the geometrical parameters associated with the nodes.

9. The method according to claim 1, wherein each node of the graph model is associated with a volume of void parameter, and:
the volume of void parameter assigned to a node corresponding to the porous matrix comprises one of a volume of void value of the porous matrix or a porosity value;
the volume of void parameter assigned to a node corresponding to a surface discontinuity comprises one of a volume value or an aperture; and
the volume of void parameter assigned to a node corresponding to a conduit comprises one of a volume value, a radius, or a diameter.

10. A method of computing a flow field within a model of a reservoir, wherein the reservoir comprises three media including a porous matrix, surface discontinuities within the porous matrix, and conduits within the porous matrix, the method comprising:
building a graph model of the reservoir by application of the method according to claim 1; and
computing a flow field within the reservoir, using a finite volume resolution method applied to the graph model.

11. The method according to claim 10, further comprising simulating reactive transport within the reservoir based on the computed flow field.

12. The method according to claim 11, wherein simulating reactive transport within the reservoir comprises simulating the displacement of particles representing a fluid along a path within the graph model of the reservoir, and updating at least some of the parameters associated with the nodes of the path of the particles.

13. The method according to claim 12, further comprising updating the three-dimensional meshed model of the reservoir according to the updated parameters associated with the nodes of the graph model, and displaying the updated three-dimensional meshed model.

14. A non-transitory computer-readable storage medium having stored thereon code instructions which, when executed by a computer, cause said computer to implement the method according to claim 1.

15. A computing device comprising at least a processor and a memory, configured for implementing the method according to claim 1.
